(19) United States
(12) Patent Application Publication
(10) Pub. No.: US 2006/0148204 A1
(43) Pub. Date: Jul. 6, 2006

(54) Monitoring pattern for optimization of chemical mechanical polishing process of trench isolation layer and related methods

(76) Inventor: Jung Ho Kang, Bucheon-si (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(21) Appl. No.: 11/324,170

(22) Filed: Dec. 29, 2005

(30) Foreign Application Priority Data
Dec. 31, 2004 (KR) 10-2004-0117831

(51) Int. Cl. H01L 21/76

(52) U.S. Cl. 438/424

(57) ABSTRACT

A monitoring pattern includes unique active area arrays, each having at least two active areas separated and defined by a trench isolation area filled with a trench isolation layer. Each active area array differs from the others in shape, size, spaced distance, extending direction, and/or density. In a monitoring method, after the monitoring pattern is formed, preferably in scribe lanes, optical images of the active area arrays are obtained. Digital optical data is produced from the optical images and then checked to monitor a CMP process. The digital optical data contain information on the active area arrays and variable information according to height of each active area array. The CMP process may be performed until a polishing target established from the digital optical data is reached.

This U.S. non-provisional application claims priority under 35 U.S.C. §119 from Korean Patent Application No. 2004-117831, which was filed in the Korean Intellectual Property Office on Dec. 31, 2004, the contents of which are incorporated by reference herein in its entirety.

### BACKGROUND OF THE INVENTION

1. Field of the Invention

The present invention relates generally to monitoring technologies for a semiconductor device fabrication process and, more particularly, to a pattern for monitoring a process for chemical mechanical polishing (CMP) a trench isolation layer and related methods.

2. Description of the Related Art

Isolation technologies, such as LOCOS (local oxidation of silicon) and STI (shallow trench isolation), are frequently used for electrically isolating active areas in semiconductor devices. STI is a relatively new technology as an alternative to LOCOS, which has limitations due to creation of an unfavorable “bird's beak.” An STI structure eliminates some problems traditionally associated with LOCOS, while enabling the active areas with higher density. Additionally, the STI structure can provide the flatness of the resulting wafer, enabling more precise pattern definition for subsequent layers. For this, the STI structure uses a planarization process, such as CMP, for flattening (or planarizing) a trench isolation layer.

FIGS. 1A to 1C show, in cross-sectional views, general profiles of the STI structure before and after the CMP process is performed.

Referring to FIG. 1A, a pad oxide layer 11 and a pad nitride layer 12 are formed in sequence on a silicon substrate 10. Both pad layers 11 and 12 are selectively etched (e.g., photolithographically patterned and etched using the patterned photoresist as a mask) to expose portions of the substrate 10, and the exposed portions are partially etched to form a trench 13 therein. Then a liner oxide layer 14 is formed on inner walls of the trench 13 (generally by thermal oxidation), and a trench isolation layer 15 is deposited sufficiently to fill the trench 13.

As shown in FIG. 1B, the trench isolation layer 15 is planarized to a polishing target 16 using the CMP process. Then the remaining pad layers 12 and 11 are wholly removed (typically by wet etching), thereby forming an STI structure 20 as shown in FIG. 1C.

FIG. 1C shows an ideal profile of the STI structure 20. To obtain the ideal profile, the CMP process should provide very high uniformity across the entire wafer. It is, however, difficult in practice to attain a desired uniformity in the CMP process. Generally, the wafer has a variety of different patterns in the active areas, and the polishing target (or polishing target height) may vary according to configuration, density, etc. of the active area patterns. This may result in poor uniformity in the CMP process and thereby cause unfavorable phenomena.

FIG. 2 shows examples of unfavorable phenomena caused by poor uniformity in the CMP process.

Referring to FIG. 2, when the trench isolation layer 15 is poorly planarized (e.g., when the trench isolation layer 15 remains over the pad nitride layer 12, perhaps due to the polishing target differing from the uppermost surface of the pad nitride layer 12), the trench isolation layer 15 may partially remain on the pad nitride layer 12 as indicated by reference numeral 21. The remaining trench isolation layer 15 may act as an obstacle to the removal of both pad layers 12 and 11. In addition, the trench isolation layer 15 may be excessively polished, and as a result, the pad layers 12 and 11 may be attacked or removed in the CMP process. This may cause damage, as indicated by reference numeral 22, of the silicon substrate 10 during the subsequent process of removing the pad layers 12 and 11.

It is therefore required in the art to establish optimum polishing targets according to various patterns of the active areas.

### SUMMARY OF THE INVENTION

Exemplary, non-limiting embodiments of the present invention provide a monitoring pattern (or monitor) for optimum polishing targets in a process for chemical mechanical polishing a trench isolation layer and related methods.

According to an exemplary embodiment of the present invention, the monitoring pattern comprises a plurality of unique active area arrays, in which each array includes at least two active areas separated and defined by a trench isolation area filled with a trench isolation layer. Each active area array differs from the others in shape, size, spaced distance, extending direction (e.g., orientation), and/or density.

In the monitoring pattern, the plurality of active area arrays may be formed in scribe lanes of a wafer. Furthermore, each of the active area arrays may have a specific optical image different from the others.

Another exemplary embodiment of the present invention relates to a method of monitoring a process of chemical mechanical polishing a trench isolation layer. The monitoring method may comprises forming a monitoring pattern (or a monitor) that includes a plurality of unique active area arrays, each array having at least two active areas separated and defined by a trench isolation area. Each active area array differs from the others in shape, size, spaced distance, extending direction, and/or density. The monitoring method further comprises obtaining optical images of the plurality of active area arrays, producing digital optical data from the optical images, and monitoring the chemical mechanical polishing process by checking the digital optical data. The digital optical data contain information on the active area arrays and variable information according to heights of each active area array.

The monitoring method may further comprise establishing a polishing target from the digital optical data after producing the digital optical data. In the monitoring method, the plurality of active area arrays may be formed in scribe lanes of a wafer.

According to still another exemplary embodiment of the present invention, a method for chemical mechanical polishing (CMP) a trench isolation layer is provided. The CMP method may comprises forming a monitoring pattern in scribe lanes of a wafer. The monitoring pattern includes a plurality of active area arrays, each array having at least two active areas separated and defined by a trench isolation area. Each active area array differs from the others in shape, size, spaced distance, extending direction, and/or density. The CMP method further comprises obtaining optical images of the plurality of active area arrays, producing digital optical data from the optical images, establishing a polishing target from the digital optical data, and performing a chemical mechanical polishing process up to the polishing target. The digital optical data contain information on the active area arrays and variable information according to heights of each active area array.

### BRIEF DESCRIPTION OF THE DRAWINGS

FIGS. 1A to 1C are cross-sectional views showing general profiles of a shallow trench isolation (STI) structure before and after the CMP process is performed.

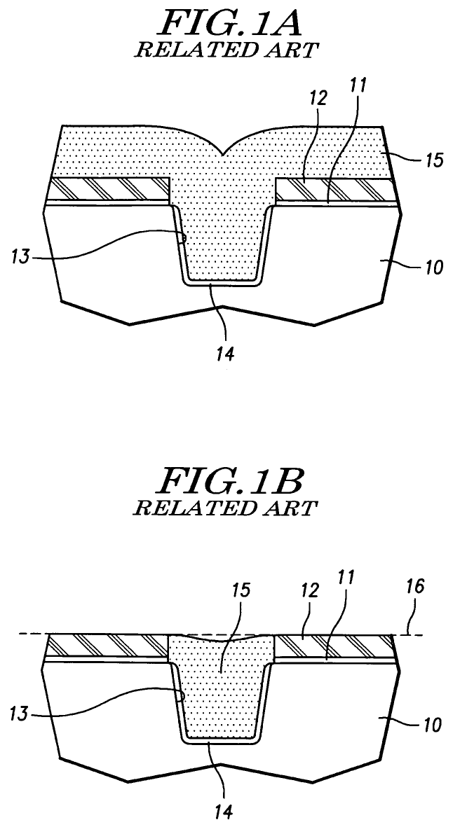

FIG. 2 is a cross-sectional view showing unfavorable phenomena caused by poor uniformity in the CMP process.

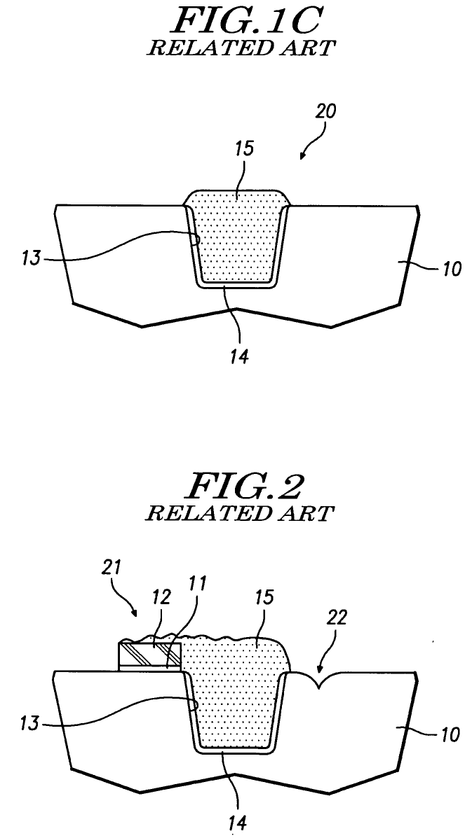

FIG. 3 is a plan view showing a monitoring pattern for the CMP process of a trench isolation layer in accordance with an exemplary embodiment of the present invention.

FIG. 4 is a cross-sectional view taken along the line IV-IV in FIG. 3.

### DETAILED DESCRIPTION OF THE INVENTION

An exemplary, non-limiting embodiment of the present invention will now be described more fully hereinafter with reference to the accompanying drawings. This invention may, however, be embodied in many different forms and should not be construed as limited to the exemplary embodiment set forth herein. Rather, the disclosed embodiment is provided so that this disclosure will be thorough and complete, and will fully convey the scope of the invention to those skilled in the art. The principles and features of this invention may be employed in varied and numerous embodiments without departing from the scope of the invention.

It is noted that well-known structures and processes are not described or illustrated in detail to avoid obscuring the essence of the present invention. It is also noted that the figures may not be drawn to scale. Rather, for simplicity and clarity of illustration, the dimensions of some of the elements may be exaggerated relative to other elements.

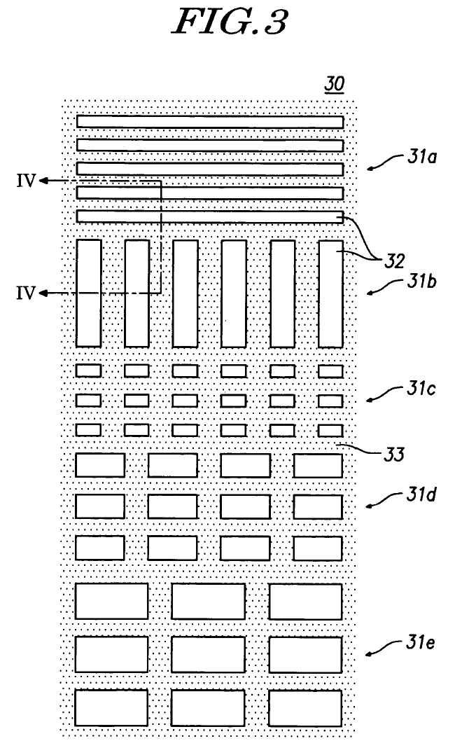

FIG. 3 shows, in a plan view, a pattern 30 for monitoring the CMP process of a trench isolation layer in accordance with an exemplary embodiment of the present invention.

Referring to FIG. 3, the monitoring pattern 30 includes a plurality of active area arrays 31a, 31b, 31c, 31d and 31e. Each active area array 31a˜31e comprises several active areas 32, which are separated and defined by an STI field area 33, and arranged in an x-by-y array of rows and/or columns where x and y are each an integer of at least 1, and at least one of x and y is an integer of at least 2. Preferably, at least one of x and y is an integer of at least 3, and x*y is an integer of at least 5.

As is well known, a wafer has a great number of integrated circuit chips, which are separated by scribe lanes. The chips may have different (or unique) patterns of active areas, the active area patterns being defined by dimensions such as shape of the active area, size of the active area, spaced distance (i.e., the spacing between active areas along a given dimension), extending direction (or orientation of a particular axis), and density (or number of active areas in an array per unit area). The monitoring pattern 30 may be designed to reflect such different patterns of the chip active areas, so the active area arrays 31a˜31e may contain differences in active area shape, size, spaced distance, extending direction, and/or density. The monitoring pattern 30 may be formed (or located) in the scribe lanes of the wafer.

The active area 32 may exhibit a different color from the field area 33 since the material(s) and/or optical properties of active area 32 are different from the field area 33. Particularly, even the active areas 32 of a first array (e.g., 31a) may have a different color than a second array (e.g., 31b) according to their patterns, so the active area arrays 31a˜31e may have their own different (or unique) colors. Such colors of the active area arrays 31a˜31e may change gradually during the CMP process, since a trench isolation layer above the active areas 32 becomes thinner and thinner by the CMP process.

It is possible to extract special optical images from the respective colors of the active area arrays 31a˜31e using typical or conventional image-extracting techniques. It is further possible to digitize the extracted optical images using well-known digital image processing tools (that is, to produce digital optical data from the optical images). Consequently, the digital optical data can contain not only specific information on the respective active area arrays 31a˜31e, but also variable information according to heights of each active area array 31a˜31e.

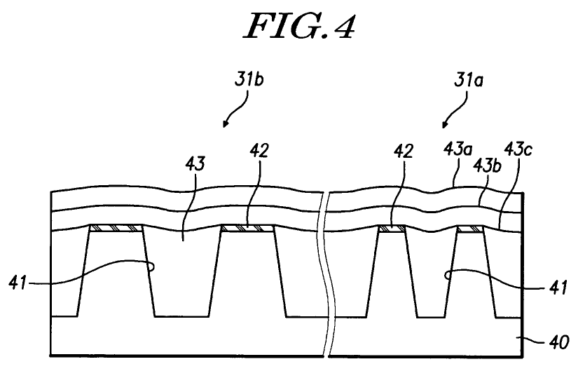

FIG. 4 is a cross-sectional view taken along the line IV-IV in FIG. 3, thereby showing two active area arrays 31a and 31b, which will be referred to as a first active area array 31a and a second active area array 31b.

Referring to FIGS. 3 and 4, a trench 41 for the field area 33 is formed in a silicon substrate 40, separating and defining the active areas 32 covered with a pad nitride layer 42. The trench isolation layer 43 is deposited over all the areas 32 and 33 of the wafer, filling the trench 41. The trench isolation layer 43 may comprise an oxide (e.g., silicon dioxide) and be formed using conventional CVD techniques. In FIG. 3, the pad oxide layer and liner oxide layer are not illustrated for clarity. Additionally, reference numerals 43a, 43b and 43c indicate respective heights of a top surface of the trench isolation layer 43 as the top surface is lowered during the CMP process.

The first and second active area arrays 31a and 31b may have different digital optical data due to different patterns of their active areas 32. Further, each active area array 31a and 31b may have different digital optical data, depending on the height of the trench isolation layer 43. For example, suppose that the digital optical data indicate ‘200’ in the first active area array 31a and ‘300’ in the second active area array 31b when the top surface of the trench isolation layer 43 lies at a first height 43a.

While the CMP process proceeds, the first height 43a of the trench isolation layer 43 is lowered or reduced to a second height 43b. Therefore, the digital optical data may change, for example, from ‘200’ to ‘240’ in the first active area array 31a and from ‘300’ to ‘330’ in the second active area array 31b. As the CMP process further proceeds, the height of the trench isolation layer 43 decreases further and further, and thereby the digital optical data change continuously. When the trench isolation layer 43 has a third height 43c, the digital optical data is changed, for example, to ‘275’ in the first active area array 31a and to ‘355’ in the second active area array 31b.

Accordingly, if the digital optical data indicating one or more polishing targets depending on the active area arrays (or corresponding to a given array pattern as defined by the dimensions of the active area, such as shape, size, spacing, orientation and/or density, and/or the height of the trench isolation layer) are recorded and correlated to a polishing endpoint, it is possible to effectively monitor the CMP process by checking the digital optical data. Furthermore, it is possible to establish optimum polishing targets according to various patterns of the active areas in the CMP process.

While this invention has been particularly shown and described with reference to an exemplary embodiment thereof, it will be understood by those skilled in the art that various changes in form and details may be made therein without departing from the spirit and scope of the invention as defined by the appended claims.

What is claimed is:

1. A monitor for a process of chemical mechanical polishing a trench isolation layer, comprising:
a plurality of active area arrays, each active area array including at least two active areas separated and defined by the trench isolation layer,
wherein each active area array differs from the other active area arrays in shape, size, spacing, orientation, and/or density.

2. The monitoring pattern of claim 1, wherein the plurality of active area arrays are in one or more scribe lanes of a wafer.

3. The monitoring pattern of claim 1, wherein each of the active area arrays has a specific optical image different from the other active area arrays.

4. A method of monitoring a process of chemical mechanical polishing a trench isolation layer, the method comprising:
obtaining optical images of a plurality of unique active area arrays, each active area array having at least two active areas separated and defined by a trench isolation area;
producing digital optical data from the optical images, wherein the digital optical data contain information from the active area arrays and variable information according to heights of each active area array and/or of the trench isolation area; and
checking the digital optical data.

5. The method of claim 4, further comprising:
establishing a polishing target from the digital optical data after producing the digital optical data.

6. The method of claim 4, comprising forming the plurality of active area arrays in one or more scribe lanes of a wafer.

7. The method of claim 4, further comprising forming the monitor.

8. The method of claim 4, wherein each active area array differs from the other active area arrays in shape, size, spacing, orientation, and/or density.

9. The method of claim 4, wherein checking the digital optical data comprises comparing the digital optical data to a data correlated to a polishing endpoint.

10. A method of chemical mechanical polishing a trench isolation layer, the method comprising:
forming a monitoring pattern in scribe lanes of a wafer, the monitoring pattern including a plurality of unique active area arrays, each active area array having at least two active areas separated and defined by a trench isolation area;
obtaining optical images of the plurality of active area arrays;
producing digital optical data from the optical images, wherein the digital optical data contain information on the active area arrays and variable information according to heights of each active area array and/or of the trench isolation area;
establishing a polishing target from the digital optical data; and
chemical mechanical polishing the wafer.

11. The method of claim 10, wherein each active area array differs from the others in shape, size, spacing, orientation, and/or density.

12. The method of claim 10, wherein the chemical mechanical polishing is conducted until the polishing target is reached.
